(19) United States
(12) Patent Application Publication
(10) Pub. No.: US 2012/0215450 A1
(43) Pub. Date: Aug. 23, 2012

(54) DISTINGUISHING BETWEEN SENSOR AND PROCESS FAULTS IN A SENSOR NETWORK WITH MINIMAL FALSE ALARMS USING A BAYESIAN NETWORK BASED METHODOLOGY

(75) Inventors: Pradeepkumar Ashok, Austin, TX (US); Ganesh Krishnamoorthy, Schenectady, NY (US); Delbert Tesar, Austin, TX (US)

(73) Assignee: BOARD OF REGENTS, THE UNIVERSITY OF TEXAS SYSTEM, Austin, TX (US)

(21) Appl. No.: 13/402,084

(22) Filed: Feb. 22, 2012

Related U.S. Application Data
(60) Provisional application No. 61/445,614, filed on Feb. 23, 2011.

(51) Int. Cl. G06F 17/18; G01R 31/00; G06F 19/00

(52) U.S. Cl. 702/9; 702/181; 702/58

(57) ABSTRACT

A method, system and computer program product for distinguishing between a sensor fault and a process fault in a physical system and use the results obtained to update the model. A Bayesian network is designed to probabilistically relate sensor data in the physical system which includes multiple sensors. The sensor data from the sensors in the physical system is collected. A conditional probability table is derived based on the collected sensor data and the design of the Bayesian network. Upon identifying anomalous behavior in the physical system, it is determined whether a sensor fault or a process fault caused the anomalous behavior using belief values for the sensors and processes in the physical system, where the belief values indicate a level of trust regarding the status of its associated sensors and processes not being faulty.

### CROSS-REFERENCE TO RELATED APPLICATIONS

This application is related to the following commonly owned co-pending U.S. patent application:

Provisional Application Ser. No. 61/445,614, “Distinguishing Between Sensor and Process Faults in a Sensor Network with Minimal False Alarms Using a Bayesian Network Based Methodology,” filed Feb. 23, 2011, and claims the benefit of its earlier filing date under 35 U.S.C. §119(e).

### GOVERNMENT INTERESTS

The U.S. Government has certain rights in this invention pursuant to the terms of the Department of Defense-Office of Naval Research Grant No. N0014-09-1-0427.

### TECHNICAL FIELD

The present invention relates to monitoring, diagnosing and condition-based maintenance of various systems, and more particularly to using a Bayesian network based methodology to distinguish between sensor and process faults in a sensor network with minimal false alarms.

### BACKGROUND

Various physical systems employ a suite of sensors to enable comprehensive monitoring of the system. For example, automobiles, power plants, wind turbines, drilling rigs, nuclear plants, airplanes, human systems (e.g., soldier performance monitoring, patient monitoring), etc. may implement a suite of sensors to provide comprehensive monitoring of the system. However, establishing a framework to manage and best utilize the available sensing resources at any given time is a quite complex task.

One strategy in sensor data management involves “condition-based maintenance” which relies on system monitoring and analysis of the monitored data. Diagnostic techniques for analyzing such monitored data include off-line signal processing (e.g., vibration analysis, parametric modeling), artificial intelligence (e.g., expert systems, model-based reasoning), pattern recognition (e.g., statistical analysis techniques, fuzzy logic, artificial neural networks), and sensor fusion or multisensor integration. The specific diagnostic technique, or combination of techniques, that is selected often depends upon the complexity, and knowledge, of the system and its operating characteristics under normal and abnormal conditions.

Currently, while estimating the existing condition or state of the system, the condition-based maintenance algorithms make the implicit assumption that all the sensors that are monitoring the system are operating correctly. In such cases, using data from sensors with faults can result in incorrect estimates of the monitored system's state and/or capabilities and cause false alarms with regards to the operational state, its estimated health or remaining useful life. In the worst case scenario, a sensor as well as the system it is monitoring may be developing incipient faults and it may be impossible to distinguish between the two. Finally, a change in sensor readings might simply be due to a regular change in the operating conditions of the system (e.g., change in the output of the speed sensor when a motor controller ramps up the motor speed from standstill to its rated speed). But abnormal sensor behavior may sometimes be masked by such subtle changes in operating conditions, especially for anomalies like drift. The conundrum for any analytical procedure that is used to identify and mitigate faulty sensor data is thus to distinguish between these different scenarios and identify with some level of confidence the precise source of abnormality in the sensor readings when they occur.

By distinguishing between these different scenarios and identifying with some level of confidence the precise source of abnormality in the sensor readings when they occur, the overall life-cycle costs of the system are greatly reduced.

### BRIEF SUMMARY

In one embodiment of the present invention, a method for distinguishing between a sensor fault and a process fault in a physical system comprises designing a Bayesian network to probabilistically relate sensor data in the physical system, where the physical system comprises a plurality of sensors. The method further comprises collecting the sensor data from the plurality of sensors in the physical system. Additionally, the method comprises deriving a conditional probability table based on the collected sensor data and the design of the Bayesian network. In addition, the method comprises identifying anomalous behavior in the physical system. Furthermore, the method comprises determining, by a processor, the sensor fault or the process fault caused the identified anomalous behavior using belief values for the plurality of sensors and a plurality of processes in the physical system, where the belief values indicate a level of trust regarding the status of its associated sensors and processes not being faulty.

Other forms of the embodiment of the method described above are in a system and in a computer program product.

The foregoing has outlined rather generally the features and technical advantages of one or more embodiments of the present invention in order that the detailed description of the present invention that follows may be better understood. Additional features and advantages of the present invention will be described hereinafter which may form the subject of the claims of the present invention.

### BRIEF DESCRIPTION OF THE SEVERAL VIEWS OF THE DRAWINGS

A better understanding of the present invention can be obtained when the following detailed description is considered in conjunction with the following drawings, in which:

FIG. 1 is a configuration of a computer system configured in accordance with an embodiment of the present invention;

FIG. 2 is a flowchart of a method for managing a physical system with multiple sensors in accordance with an embodiment of the present invention;

FIG. 3 is a flowchart of a method for designing a Bayesian network to quantitatively and probabilistically relate sensor data in accordance with an embodiment of the present invention;

FIGS. 4A and 4B depict two Bayesian network structures illustrating the design criteria of maximizing the number of links directly inbound/outbound to a sensor identified as important for operational reasons in accordance with an embodiment of the present invention;

FIGS. 5A and 5B depict two Bayesian network structures illustrating the design criteria of arranging sensor network nodes according to their precedence in time or according to their functional relationship in accordance with an embodiment of the present invention;

FIGS. 6A and 6B depict two Bayesian network structures illustrating the design criteria of attaching as many sensor nodes to the sensor nodes with higher reliability in accordance with an embodiment of the present invention;

FIGS. 7A and 7B depict two Bayesian network structures illustrating the design criteria of designing a network of nodes in a serial manner versus a parallel manner to reduce memory requirements in accordance with an embodiment of the present invention;

FIG. 8 is a flowchart of a method for optimizing the use of the sensors in the physical system in accordance with an embodiment of the present invention;

FIGS. 9A and 9B depict two Bayesian network structures illustrating the operational criteria of determining the sensor that is most likely to provide a best estimate of another sensor based on node distance in accordance with an embodiment of the present invention;

FIG. 10 is a flowchart of a method for distinguishing between sensor and process faults in accordance with an embodiment of the present invention;

FIG. 11 depicts a Bayesian network structure used in explaining sensor faults and process faults in accordance with an embodiment of the present invention;

FIG. 12 depicts a Bayesian network structure used in explaining how to distinguish between a sensor fault and a process fault in accordance with an embodiment of the present invention; and

FIG. 13 is an instantiation table for the network shown in FIG. 12 in accordance with an embodiment of the present invention.

### DETAILED DESCRIPTION

In the following description, numerous specific details are set forth to provide a thorough understanding of the present invention. However, it will be apparent to those skilled in the art that the present invention may be practiced without such specific details. In other instances, well-known circuits have been shown in block diagram form in order not to obscure the present invention in unnecessary detail. For the most part, details considering timing considerations and the like have been omitted inasmuch as such details are not necessary to obtain a complete understanding of the present invention and are within the skills of persons of ordinary skill in the relevant art.

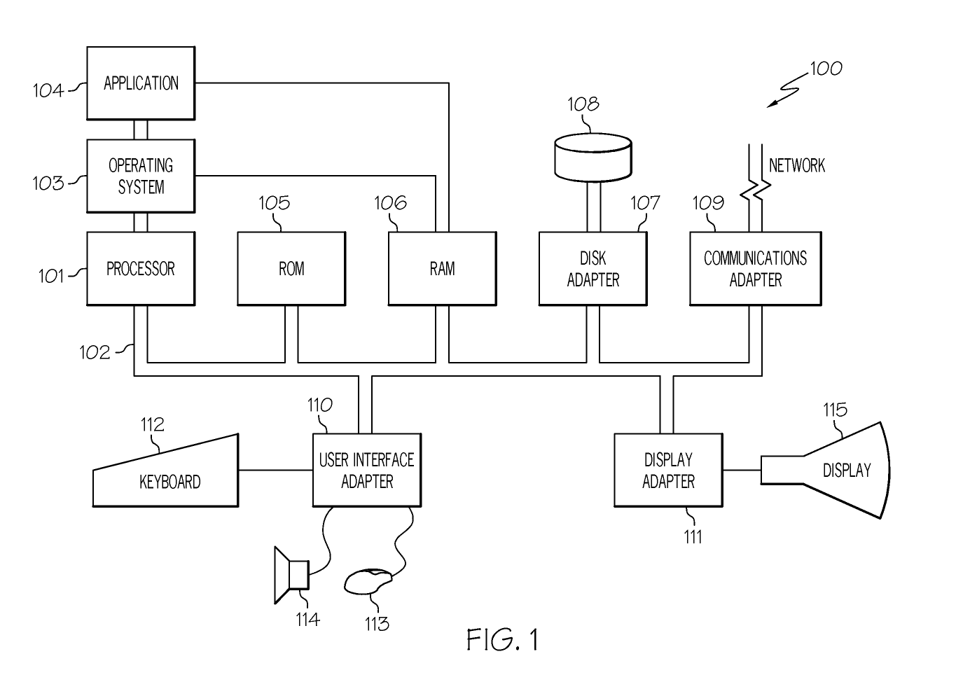

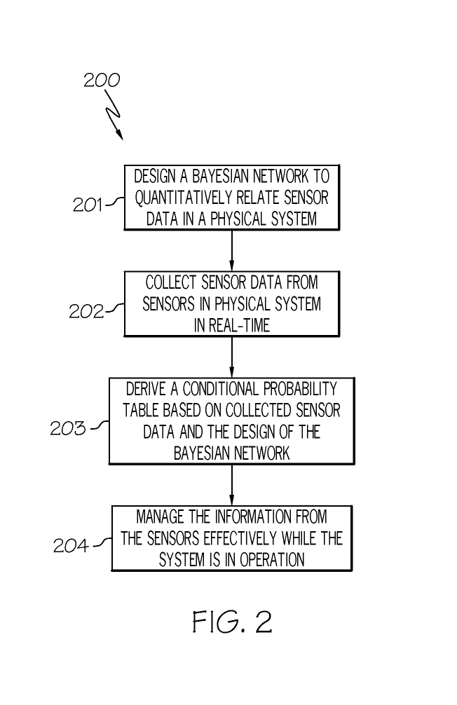

Referring now to the Figures in detail, FIG. 1 illustrates an embodiment of a hardware configuration of a computer system 100 which is representative of a hardware environment for practicing the present invention. In one embodiment, computer system 100 is attached to sensors (not shown), sensing activities, events, physical variables, etc., occurring in the system. Referring to FIG. 1, computer system 100 may have a processor 101 coupled to various other components by system bus 102. An operating system 103 may run on processor 101 and provide control and coordinate the functions of the various components of FIG. 1. An application 104 in accordance with the principles of the present invention may run in conjunction with operating system 103 and provide calls to operating system 103 where the calls implement the various functions or services to be performed by application 104. Application 104 may include, for example, an application for distinguishing between sensor and process faults in a sensor network with minimal false alarms as discussed further below in association with FIGS. 2-3, 4A-4B, 5A-5B, 6A-6B, 7A-7B, 8, 9A-9B and 10-12.

Referring again to FIG. 1, read-only memory (“ROM”) 105 may be coupled to system bus 102 and include a basic input/output system (“BIOS”) that controls certain basic functions of computer device 100. Random access memory (“RAM”) 106 and disk adapter 107 may also be coupled to system bus 102. It should be noted that software components including operating system 103 and application 104 may be loaded into RAM 106, which may be computer system's 100 main memory for execution. Disk adapter 107 may be an integrated drive electronics (“IDE”) adapter that communicates with a disk unit 108, e.g., disk drive. It is noted that the program for distinguishing between sensor and process faults in a sensor network with minimal false alarms as discussed further below in association with FIGS. 2-3, 4A-4B, 5A-5B, 6A-6B, 7A-7B, 8, 9A-9B and 10-12, may reside in disk unit 108 or in application 104.

Computer system 100 may further include a communications adapter 109 coupled to bus 102. Communications adapter 109 may interconnect bus 102 with an outside network (not shown) thereby allowing computer system 100 to communicate with other similar devices.

I/O devices may also be connected to computer system 100 via a user interface adapter 110 and a display adapter 111. Keyboard 112, mouse 113 and speaker 114 may all be interconnected to bus 102 through user interface adapter 110. Data may be inputted to computer system 100 through any of these devices. A display monitor 115 may be connected to system bus 102 by display adapter 111. In this manner, a user is capable of inputting to computer system 100 through keyboard 112 or mouse 113 and receiving output from computer system 100 via display 115 or speaker 114.

As will be appreciated by one skilled in the art, aspects of the present invention may be embodied as a system, method or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present invention may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or flash memory), a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof A computer readable signal medium may be any computer readable medium that is not a computer readable storage medium and that can communicate, propagate, or transport a program for use by or in connection with an instruction execution system, apparatus or device.

Program code embodied on a computer readable medium may be transmitted using any appropriate medium, including but not limited to wireless, wireline, optical fiber cable, RF, etc., or any suitable combination of the foregoing.

Computer program code for carrying out operations for aspects of the present invention may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present invention are described below with reference to flowchart illustrations and/or block diagrams of methods, apparatus (systems) and computer program products according to embodiments of the present invention. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to product a machine, such that the instructions, which execute via the processor of the computer or other programmable data processing apparatus, create means for implementing the function/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the function/acts specified in the flowchart and/or block diagram block or blocks.

As stated in the Background section, currently, while estimating the existing condition of a system, condition-based maintenance algorithms make the implicit assumption that all the sensors that are monitoring the system are operating correctly. In such cases, using data from sensors with faults can result in incorrect estimates of the monitored system's capabilities and cause false alarms with regards to its estimated health or remaining useful life. In the worst case scenario, a sensor as well as the system it is monitoring may be developing incipient faults and it may be impossible to distinguish between the two. Finally, a change in sensor readings might simply be due to a regular change in the operating conditions of the system (e.g., change in the output of the speed sensor when a motor controller ramps up the motor speed from standstill to its rated speed). But abnormal sensor behavior may sometimes be masked by such subtle changes in operating conditions, especially for anomalies like drift. The conundrum for any analytical procedure that is used to identify and mitigate faulty sensor data is thus to distinguish between these different scenarios and identify with some level of confidence the precise source of abnormality in the sensor readings when they occur. By distinguishing between these different scenarios and identifying with some level of confidence the precise source of abnormality in the sensor readings when they occur, the overall life-cycle costs of the system are greatly reduced.

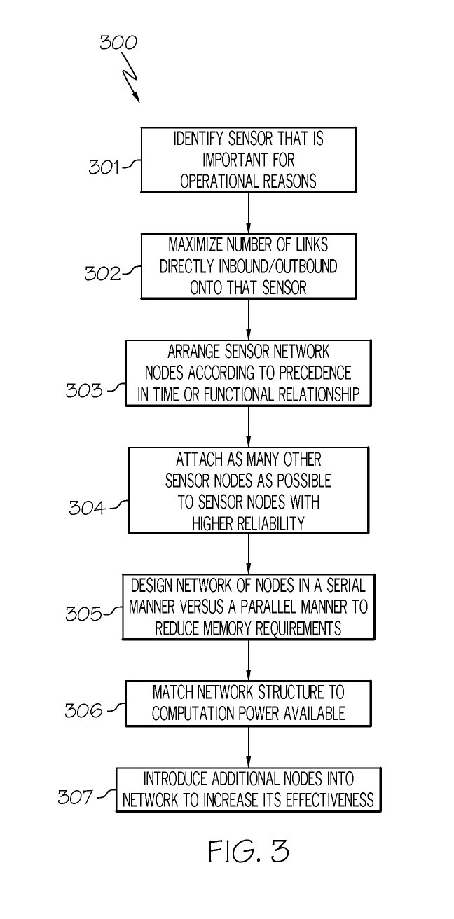

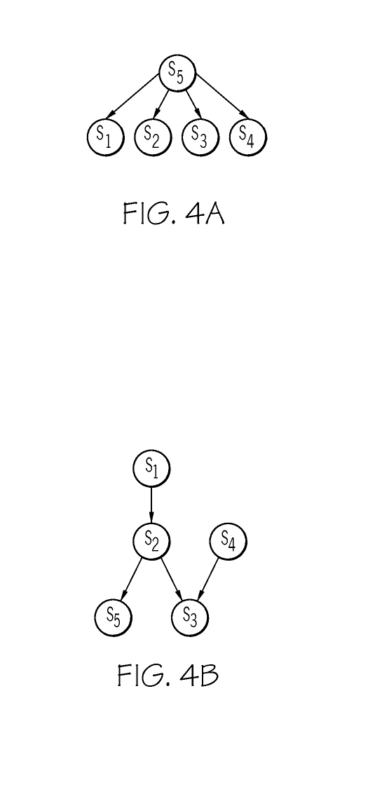

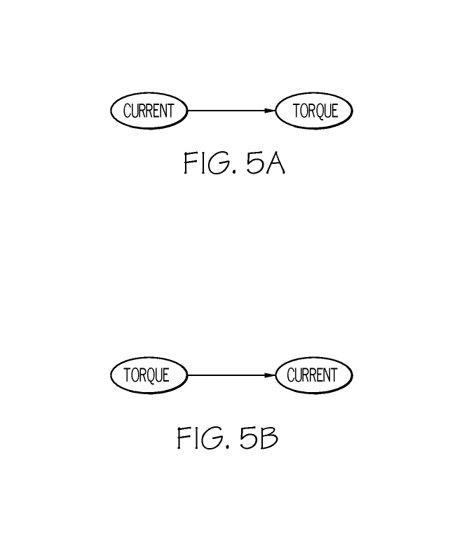

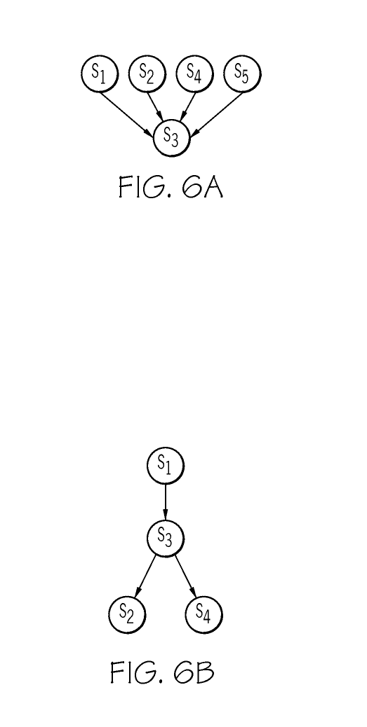

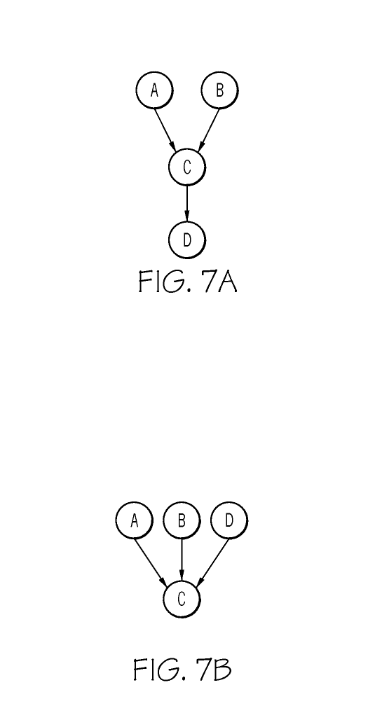

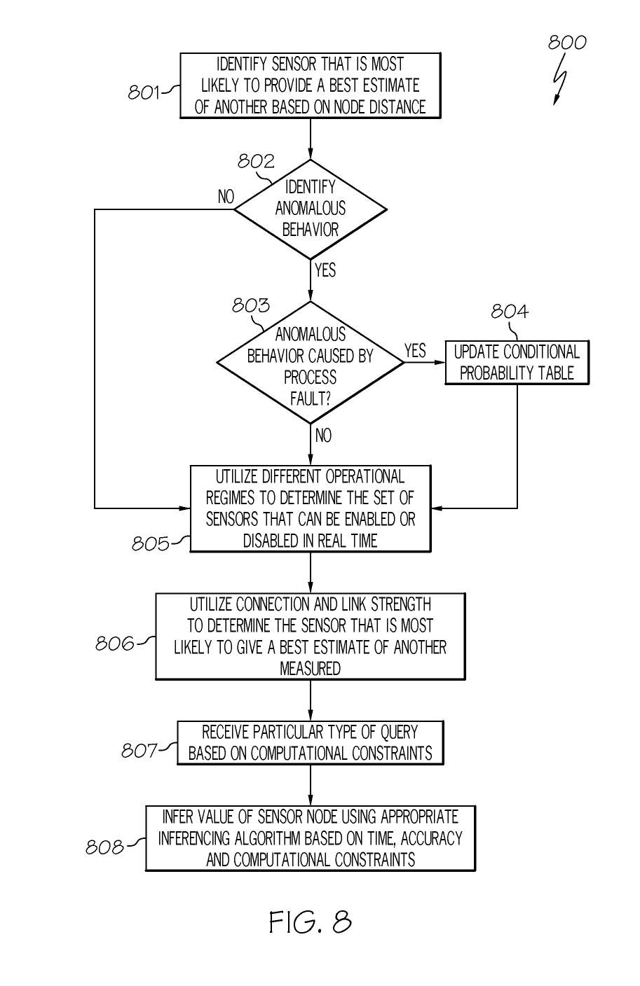

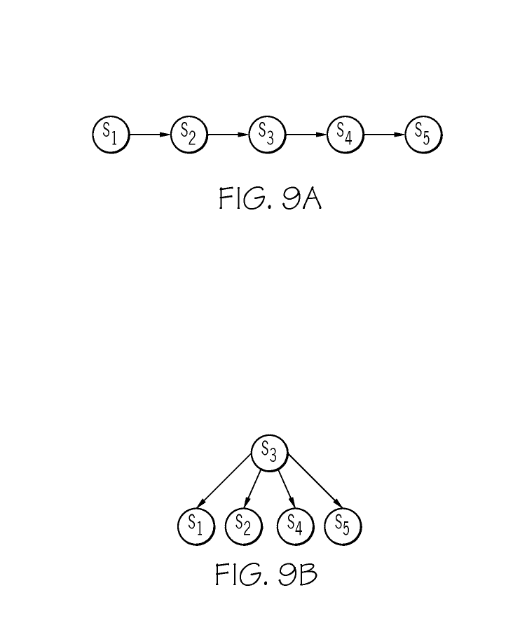

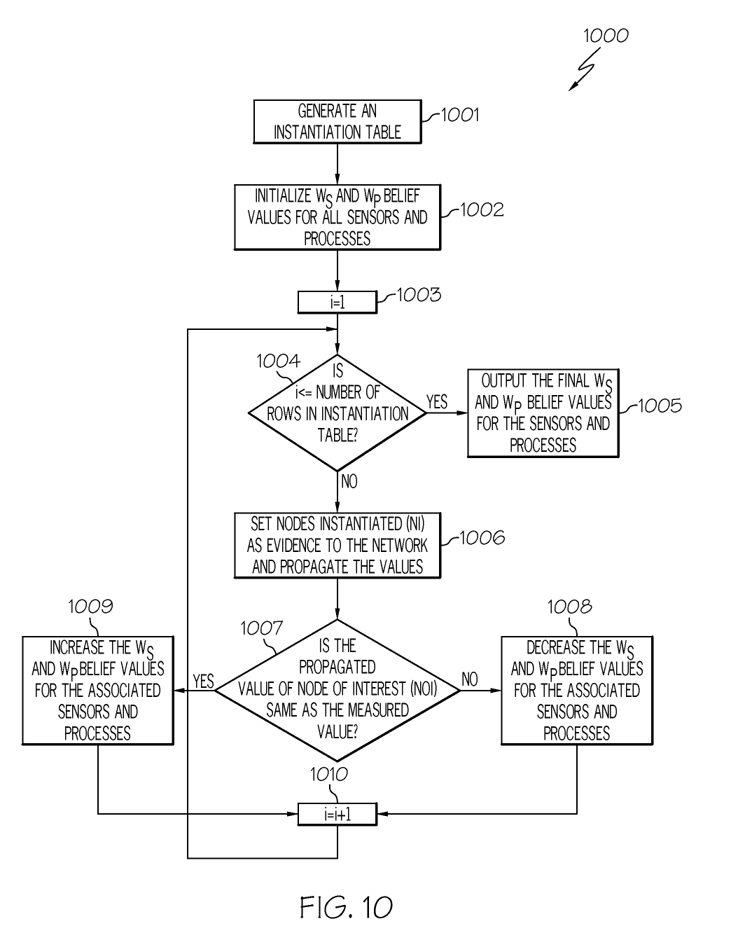

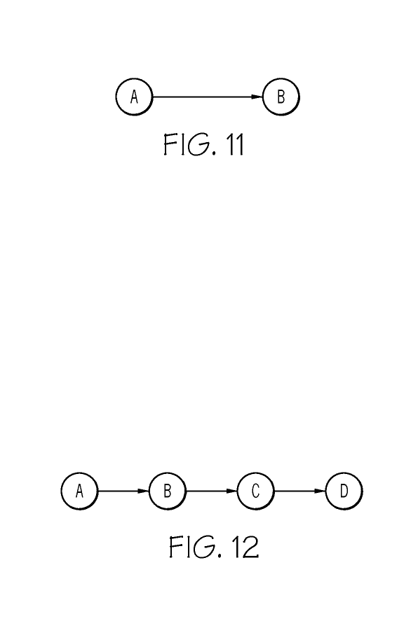

The principles of the present invention provide a technique for distinguishing between sensor and process faults and identifying the source of such faults as discussed below in connection with FIGS. 2-3, 4A-4B, 5A-5B, 6A-6B, 7A-7B, 8, 9A-9B and 10-12. FIG. 2 is a flowchart of a method for managing a physical system with multiple sensors. FIG. 3 is a flowchart of a method for designing a Bayesian network to quantitatively and probabilistically relate sensor data. FIGS. 4A and 4B depict two Bayesian network structures illustrating the design criteria of maximizing the number of links directly inbound/outbound to a sensor identified as important for operational reasons. FIGS. 5A and 5B depict two Bayesian network structures illustrating the design criteria of arranging sensor network nodes according to their precedence in time or according to their functional relationship. FIGS. 6A and 6B depict two Bayesian network structures illustrating the design criteria of attaching as many sensor nodes to the sensor nodes with higher reliability. FIGS. 7A and 7B depict two Bayesian network structures illustrating the design criteria of designing a network of nodes in a serial manner versus a parallel manner to reduce memory requirements. FIG. 8 is a flowchart of a method for optimizing the use of the sensors in the physical system. FIGS. 9A and 9B depict two Bayesian network structures illustrating the operational criteria of determining the sensor that is most likely to provide a best estimate of another sensor based on node distance. FIG. 10 is a flowchart of a method for distinguishing between sensor and process faults. FIG. 11 depicts a Bayesian network structure used in explaining sensor faults and process faults. FIG. 12 depicts a Bayesian network structure used in explaining how to distinguish between a sensor fault and a process fault.

As stated above, FIG. 2 is a flowchart of a method 200 for managing a physical system with multiple sensors in accordance with an embodiment of the present invention. A physical system, as used herein, refers to any type of system that employs a suite of sensors to monitor its system. For example, automobiles, nuclear reactors, wind turbines, airplanes, power distribution systems, human systems (e.g., soldier performance monitoring), drilling rigs, chemical plants, patient health monitoring systems, etc. may implement a suite of sensors to provide comprehensive monitoring of the system.

Referring to FIG. 2, in conjunction with FIG. 1, in step 201, a Bayesian network is designed to quantitatively and probabilistically relate sensor data in a physical system. Bayesian network theory provides a mathematical tool to link/associate the sensors and to quantitatively and probabilistically relate the sensor data. Such a Bayesian network may be designed in step 201 using various factors as discussed below in connection with FIG. 3.

FIG. 3 is a flowchart of a method 300 for designing a Bayesian network to quantitatively and probabilistically relate sensor data in a physical system in accordance with an embodiment of the present invention. The Bayesian network may be designed using one or more of the factors discussed in connection with method 300.

In one embodiment, the nodes in the Bayesian network represent the different physical parameters of interest for which sensors are integrated into the physical system. The Bayesian network is designed to mirror the actual physical system as closely as possible since it is meant to represent the behavior of the system during operation. As a result, the process discussed below is iterative, as there are numerous design criteria that need to be balanced simultaneously.

To be clear, the design criteria discussed below is not only used to determine the choice of sensors while designing the physical system but also to address some of the requirements in creating the Bayesian network representation of it (e.g., determining relevant nodes, the ordering of the nodes).

Referring to FIG. 3, in conjunction with FIGS. 1 and 2, in step 301, the sensor that is important for operational reasons is identified. In step 302, the number of links directly inbound/outbound to the sensor identified in step 301 is maximized.

In any application, there are essential sensors without which it may be impossible to achieve satisfactory system operation and additionally there may be optional sensors that are used to monitor some secondary parameters of interest to enable enhanced system performance.

In certain applications, the sensors corresponding to the critical variables of interest may be too fragile and may be prone to frequent failure or loss of performance (for instance, high precision position encoders are usually sensitive to high operating temperatures). Any degradation or unexpected loss of information from such a sensor vital to the system, may lead to undesirable system behavior or in the extreme case, a catastrophic system failure.

In such situations, if the sensors are too expensive to replace or are located in an inaccessible location within the system and it is not possible to replace or repair them when the system is in operation without other consequences (altering the system, downtime costs incurred as a result of shutting down the system for repair, etc.), it may be desirable to provide some failsafe provision for obtaining these critical measurands, in case of a loss of information from their corresponding sensors.

With the use of a Bayesian network to provide functional redundancy, data from one or more of the other operational sensors can be used to probabilistically estimate (or as referred to herein to “set evidence”) the value of the node corresponding to the sensor of interest that has been identified as the sensor of importance. In terms of the network structure, this means that the node corresponding to the sensor of interest should be related to as many other nodes as possible. The objective is to provide as many alternative sources of information as possible to infer the critical measurands of the sensor of interest so that failsafe operation is possible. Different network structures can produce data of differing quality. The most suitable network would be one where the value of the sensor of interest can be obtained from the node(s) which can potentially be set as evidence, without the need to traverse through a lot of intermediate nodes or links.

For example, referring to FIGS. 4A and 4B, FIGS. 4A and 4B illustrate two possible Bayesian network structures representing a relation between five variables of interest S₁, S₂ . . . S₅ with S₅ being the most critical measurand in accordance with an embodiment of the present invention. Consider the case where there is a loss of information from the sensor corresponding to S₅. As illustrated in FIG. 4A, the value of the node S₅ can be inferred using data from any of the sensors corresponding to nodes S₁ through S₄ with only one intermediate link involved. The uncertainty in the inferred value of S₅ is determined by the relationships S₅->Sᵢ as encoded in the conditional probabilities P(Sᵢ|S₅), where i=1, 2, 3, 4. Even if one or more of the other sensors S₁ . . . S₄ become partially or completely unavailable, an alternative exists to infer the value of S₅ (except in the extreme case where all the sensors S₁ . . . S₄ become unavailable). However, in FIG. 4B, the best option available to infer the value of S₅ with least uncertainty is by setting the value of the sensor corresponding to S₂ as evidence to the network. Although any of the other sensors S₁ . . . S₄ may still be used to infer the value of S₅, if the sensor corresponding to S₂ also becomes unavailable, the uncertainty in the inferred value will be higher.

In step 303, the sensor network nodes are arranged according to their precedence in time or according to their functional relationship.

The topology of a Bayesian network may be highly influenced by the ordering of the nodes that represent the variables in the system under consideration. In one embodiment, the links in a Bayesian network represent the conditional independencies between the connected nodes and need not necessarily represent causal relationships between those nodes. However, using causal relations to represent the links between the nodes can help attribute physical meaning to the values that are obtained using the network, making it more intuitive for the user to comprehend those values and use them in decision making.

For instance, consider a network with two nodes, current and torque, representing a motor. Assume that comprehensive experimental data regarding both the variables is available over the entire operating range in an application where the motor is used and can be used to create the required conditional probability tables. Conditional probability tables are tables that store probability values which correspond to the probability of the sensor(s) having particular values (discussed further below). The relation between them can be represented as two possible Bayesian network structures as shown in FIGS. 5A and 5B in accordance with an embodiment of the present invention. FIG. 5A illustrates the current node linking to the torque node; whereas, FIG. 5B illustrates the torque node linking to the current node. From a mathematical perspective, both the above networks are equally valid since both forward and inverse probabilistic reasoning based on available information i.e., P(Torque|Current) or P(Current|Torque), are possible by simply using the conditional probability tables or Bayes' theorem, as the case may be. But for both experts (who are involved in designing the system and its Bayesian network representation) and non-experts (who may be the end users making the final decisions for operating the system), the structure shown in FIG. 5A will provide a greater intuition in decision making since it represents what actually happens in a motor (i.e., the current applied across the motor windings results in torque generated by the motor (due to the air-gap magnetic field) and not the other way around).

It is believed that a causal model underlies any real-world joint probability distribution and typically results in a Bayesian network that can be considered practically useful. As a result, conditions may be used to determine whether a variable (e.g., A) causes another variable (e.g., B) or not and hence also examine the direction of the link between A and B in the Bayesian network.

For example, one condition may be precedence in time. For a variable A to cause a change in a variable B, A must temporally happen before B. This implies that the causal relation is asymmetric. Another condition may be a functional relationship. There is a function relationship between the cause and the effect parameters (B=f(A)). If the knowledge of one variable does not provide any additional information regarding the other variable, then they can be considered as independent of each other. If not, then they are related. A further condition could be non-spuriousness. The relation between A and B should not be influenced by the presence of a third variable C that causes both A and B, such that if C is controlled, then A and B become independent.

In step 304, as many sensor nodes should be attached to the sensor nodes with higher reliability. As used herein, sensor nodes refer to nodes sensing physical variables, such as current or speed, as well as sensing an activity or event (both normal or abnormal) occurring in the system of interest. For example, sensor nodes may detect when a motor has stopped or when a motor has switched to a different operating level. The measurements for these nodes may be obtained from algorithms/applications or from humans.

Sensors can be affected by a number of factors in their operational environment. Factors like heat/temperature cycling, mechanical shock/vibrations, humidity, power-on/power-off cycling, etc., can sometimes have detrimental effects on the on-board signal processing electronics (for instance, oxidation and failure in solder joints, fretting leading to unreliable contacts). For sensors not based on a non-contact operating principle, the sensing element may itself undergo wear and tear due to physical contact. In most cases, the data from sensors is sent to a remote data acquisition device or a computer, where it is transformed into useful information (for instance, performance maps) that may be used for decision making. In this process, data from sensors may become unavailable due to a fault in intermediate connectors or wiring that conveys the sensor output signal to the processor (the analogous situation in case of wireless sensors would be a fault in the transmission link). Most sensors also need a power supply; a fault in the power leads may cause the sensor to become inoperative. All the factors described above may be taken together as representative of how reliable a sensor is.

Reliability is often expressed as the probability that the sensor will function without failure over a certain time or a specified number of cycles of use. A common metric for specifying reliability indirectly is in terms of mean time between failure (MTBF) which is the average expected time between failures of like units under like conditions (e.g., MTBF=total time exposure for all installed units/number of failures).

If such data is available for any system, for example, based on the operational history of the system and the various sensors integrated into it, the knowledge may be used to refine the structure of the Bayesian network for future versions of the system. The nodes corresponding to sensors which are traditionally found to be extremely reliable may be connected to as many other nodes as possible, representing other sensors which may be less reliable, in order to provide a greater assurance of back-up information being available in case of a loss of information from the unreliable sensors.

FIGS. 6A and 6B depict two possible Bayesian network structures illustrating sensor reliability in accordance with an embodiment of the present invention. Referring to FIGS. 6A and 6B, suppose that the sensor corresponding to the node S₃ is considered to be the most reliable amongst all the available sensors. In case one of the sensors S₁, S₂ . . . etc. becomes unavailable, then the network structures shown in FIGS. 6A and 6B can help infer the value of those sensors using the value of S₃ within acceptable limits (depending on the quality of data used to generate the conditional probability tables).

In step 305, the network of nodes is designed in a serial manner versus a parallel manner to reduce memory requirements.

By exploiting the conditional dependencies/independencies between the different random variables of interest (embedded explicitly in the network structure in the form of the links between the nodes corresponding to the variables), a Bayesian network allows compact storage of their joint probability distribution locally in the form of conditional probability tables for all the non-root nodes in the network. The resultant form of the conditional probability tables may have a significant impact on the usefulness of the overall network in addressing the system's operational goals.

Consider two possible network structures that relate variables of interest in a system A, B, C, D as illustrated in FIGS. 7A and 7B in accordance with an embodiment of the present invention. Assume that each variable has two states True or False. In FIG. 7A, the total number of parameters in the conditional probability tables of A, B and D is 2 each, whereas, the number of parameters in the conditional probability table of C is 8. In FIG. 7B, the number of parameters in the conditional probability tables of A, B and D is again 2 each but the number of parameters in the conditional probability table of C is now 16. If one unit of memory is required to store each parameter, the total memory required in the first case is 16 units but increases to 22 units in latter case. With a more complex network, there may be several nodes with a large number of parents, a high degree of interlinking among the nodes, and a large number of individual states for each node. The size of the conditional probability table for a node grows exponentially in terms of the number of parents. For a node with n states and i=1, 2, 3 . . . k parents, if Sᵢ is the number of states for the i^{th} parent, the size of the conditional probability table for that node is n rows and

$$m = {\prod }_{i = 1}^{k} {S}_{i}$$

columns and the total number of parameters in the conditional probability table is n×m. Thus, the size of the individual conditional probability tables and the total memory requirements can quickly spiral out of control.

Even though the cost of memory/storage may not be expensive compared to the cost of other components in the system, the on-board memory available for storing the conditional probability tables may be limited due to factors like storage requirements for other programs/functions that are needed for effective system control and operation. Hence, the memory requirements may be taken into account while designing the network. Various techniques may be used to modify both the structure of the network (and the resultant size of condition probability tables as well memory required to store and manipulate them). These include the judicious selection of the number of levels of discrete states that are needed for every node in the network (especially for nodes which are connected to a child node with many other parent nodes), use of canonical models such as noisy-OR, noisy-MAX, etc., which reduces the number of parameters required to completely specify the conditional probability tables, the introduction of intermediate nodes to “divorce” parent nodes and partition their configurations which has the result of reducing the number of parent nodes associated with a given node, the use of decision trees or graphs, propositional rules (if-then), deterministic conditional probability tables (with only 0 or 1 as probability values), etc.

In step 306, the network structure is matched to the computation power available. While more nodes in a Bayesian network imply a greater confidence in the sensors and the system, they come with a computational overload. As a result, the network structure should be matched to the computation power available.

In step 307, additional nodes are introduced into the network to increase its effectiveness. Additional nodes, representing redundant sensors, may be introduced into the network to improve the effectiveness of the system such that when a sensor fails, its duplicate sensor can continue the operation of the failed sensor.

In some implementations, method 300 may include other and/or additional steps that, for clarity, are not depicted. Further, in some implementations, method 300 may be executed in a different order presented and that the order presented in the discussion of FIG. 3 is illustrative. Additionally, in some implementations, certain steps in method 300 may be executed in a substantially simultaneous manner or may be omitted.

Returning to FIG. 2, in step 202, sensor data from the sensors in the physical system is collected in real time.

In step 203, a conditional probability table(s) are derived based on the collected sensor data and the design of the Bayesian network. Conditional probability tables store probability values which correspond to the probability of the sensor(s) having particular values. In one embodiment, each value in the table lies between 0 and 1. For example, suppose that data was acquired from a speed sensor and a torque sensor. For example, suppose that the probability value P(Speed=6.0|Torque=30)=0.87. In this example, the probability that the speed sensor registers 6 rpm given the torque sensor registers 30 Nm is 0.87. This probability value may be obtained by combining all available speed data for the torque sensor having the value of 30 Nm.

In step 204, the information from the sensors are managed effectively while the system is in operation. Information from the sensors may be managed effectively using various criteria as discussed below in FIG. 8.

In some implementations, method 200 may include other and/or additional steps that, for clarity, are not depicted. Further, in some implementations, method 200 may be executed in a different order presented and that the order presented in the discussion of FIG. 2 is illustrative. Additionally, in some implementations, certain steps in method 200 may be executed in a substantially simultaneous manner or may be omitted.

FIG. 8 is a flowchart of a method 800 for optimizing the use of the sensors in the physical system in accordance with an embodiment of the present invention. The use of the sensors are optimized using one or more of the factors discussed in connection with method 800.

Once the system design has been completed (with the requisite sensors integrated into the system) and a representative Bayesian network has been designed for it, suitable criteria may be determined to be used for managing information from all the sensors while the system is in operation. The objective is to make the best use of the information available from the finite set of sensors and the network in conjunction with the available computational resources at any given time. These operational criteria may be used to make decisions regarding how the available sensors may be prioritized to adapt to varying task demands, determine the best options for sensors that may serve as alternatives used to infer the value of failed sensors, what sort of information can be gleaned from the network, account for constraints that may arise during operation (e.g., limited bandwidth/power), etc. Method 800 provides one or more such criteria.

In step 801, the sensor that is most likely to provide a best estimate of another sensor based on node distance is identified.

Correlating all the variables of interest in the system using a Bayesian network allows the use of any variable to infer the value of any other variable in the network (by setting the former as evidence and using probabilistic propagation to infer the desired value). However, the inferred value (and the uncertainty in it) can be heavily influenced by the number of intermediate links between the evidence node and the query node. Referring to FIG. 9A, depicting an illustrative Bayesian network structure in accordance with an embodiment of the present invention. Suppose the sensor corresponding to node S₃ has failed but all the other sensors are operating correctly. Given the network structure of FIG. 9A, it is possible to use the data from any of the remaining sensors S₁ to S₅ to set a state of their corresponding nodes as evidence and inferring the value of S₃. Intuitively, it can be expected that the uncertainty in the inferred value of S₃ will be the least when the value of S₂ is used as evidence since there is only one intermediate link between S₂ and S₃. In this case, the uncertainty in the inferred value is determined by the uncertainty in the process S₂->S₃ This relation between S₂ and S₃ is encoded in the conditional probability distribution of S₃ i.e., P(S₃|S₂).

If, however, the data from the sensor corresponding to the node S₁ is used to infer the value of S₃, then the final value is influenced by the uncertainties in two intermediate processes i.e. S₁->S₂ and S₂->S₃. In this case, the value of the node S₃ will be calculated using the chain rule of probability as P(S₃|S₁)=P(S₃|S₂)·P(S₂|S₁)·P(S₁). Since 0≦P(·|·)≦1, the value of P(S₃|S₁)≦P(S₃|S₂). In general, in the latter case, the probability distribution is spread over more states of the node S₃ with a lower probability value for each individual state. Thus, the farther away the evidence node S_{E} is from the query node S_{Q}, the greater is the potential uncertainty in the inferred value of S_{Q} since each local inference introduces additional uncertainty/deviation in the final value. This effect may be quantified by using the concept of Node Distance (ND) for a single evidence node and query node. Node Distance (ND) refers to the shortest possible path between an evidence node S_{E} and a query node S_{Q} along a directed path between the two.

Using the notation ND_{SE,SQ} the value of node distance can be calculated in terms of the number of intermediate links connecting the sequence of adjacent node pairs between S_{E} and S_{Q}. For instance, in FIG. 9A, considering the nodes S₃ and S₅, the node distance is ND_{S3, S5}=2. Similarly, ND_{S4, S5}=1. As the value of ND increases, the greater is the potential uncertainty in the inferred value. This may be a guideline used by the system operator when determining which of the operational sensors may be used to infer an unavailable value.

However, the concept of ND may not work well for certain types of network structures. Consider the illustrative Bayesian network structure of FIG. 9B configured in accordance with an embodiment of the present invention. Suppose the sensor corresponding to S₃ is determined to be faulty. Any of the remaining sensors may be used to determine the value of S₃. In this case, it is noted that even though there is only one link connecting any of the nodes Sᵢ, where i=1, 2, 4, 5 to S₃ (i.e., ND_{Si, S3}=1), the uncertainty in the final value of S₃ will be different depending on which of the nodes is used as evidence. In this case, the uncertainty in the inferred value would be dictated by the uncertainty in the relations S₃->Sᵢ encoded in the respective conditional probability distributions (i.e., P(Sᵢ|S₃)). For such network structures, the concept of link strength (discussed further below) is more suitable.

In step 802, a determination is made as to whether an anomalous behavior (e.g., sensor fault, process fault) has been identified. If an anomalous behavior has been identified, then, in step 803, it is determined if the anomalous behavior is caused from a sensor fault or a process fault. Upon determining if the anomalous behavior is caused from a sensor fault or a process fault, an indication as to whether the anomalous behavior is caused from a sensor fault or a process fault is displayed to a user via display 115. If the anomalous behavior is caused by a process fault, then, in step 804, the conditional probability table is updated.

A more detailed description of the process involving steps 802-804 is discussed in further detail in conjunction with FIG. 10. FIG. 10 is a flowchart of a method 1000 for distinguishing between sensor and process faults.

A brief discussion of what is meant by “sensor fault” and “process fault” is deemed appropriate. “Sensor fault,” as used herein, refers to a disagreement between the ideal value that the sensor is supposed to indicate under the prevalent operating conditions and the measured value it actually indicates at the sampling instant under consideration and does not necessarily mean that the sensor itself is flawed. This difference may be caused by a temporary drift, bias or noise in the reading. Hence, the output from the particular sensor would need to be tracked over multiple sampling instants to declare with certainty that the sensor itself is faulty.

The links between the different nodes in a Bayesian network represent the physical variables (e.g., torque, speed, etc.) pertinent to the system and its components. Thus, the link between every pair of nodes can be considered to be a “process” that converts the physical parameter represented by the parent node into the parameter represented by the child node. For discrete variables, the strength of the correlation between a parent node-child node pair can be said to be quantified by the conditional probability table of the child node.

Referring to FIG. 11, FIG. 11 illustrates a Bayesian network structure with two nodes in accordance with an embodiment of the present invention. In FIG. 11, the link A->B between the two nodes thus represents the “process A->B.” The parameters or the entries in the condition probability table of B represent the conditional probability distribution P(B=bᵢ|A=aⱼ), where i=1 . . . m and j=1 . . . n, are the number of states of B and A (the states represent the distinct values that these two variables can assume) respectively. If there is simply a change in the operating conditions of the system, the conditional distribution for the child node given the value of its parents would still hold valid but a fault in any system component would essentially render the relation between A and B as encoded in the condition probability table of B invalid. In other words, this would be reflected as a change in the parameters of the condition probability table of the child node B. Hence, the term “process fault” refers to a change in the relation between pairs of variables represented in the network.

The last updated set of condition probability table parameters represent the latest known information available to the operator regarding the system status before information from a new set of sensor readings becomes available. Any value deduced using the network represents the value that should ideally be obtained from the sensor corresponding to that node if there are no new or unknown problems in either the sensors or in any of the system components that have not already been accounted for. On the other hand, the sensors are sampled at a much faster rate compared to the pace at which embedded process performance parameters are updated. The values indicated by the sensors at any sampling instant indicate the extant status of the system at that instant and will therefore be influenced by any possible issues that have occurred since the embedded process parameters were last updated.

The premise of method 1000, as discussed further below, is that by sequentially instantiating different nodes in the Bayesian network (referred to as “Nodes Instantiated” or NI), performing probabilistic propagation, and examining the resultant values of other specific nodes in the network (referred to as “Node of Interest” or NoI), it may be possible to estimate the validity of the sensor readings obtained. The readings from the sensors corresponding to NI are used to set specific states of such nodes as evidence to the network. Every node in the network can be considered as a NoI sequentially one at a time, until all the nodes in the network have been traversed. For each NoI, multiple values can be estimated by considering different combinations of other nodes in the network as NI and calculating its posterior probability distribution. The values inferred for the NoI are compared with the actual values indicated by their corresponding sensors to determine if the sensors are indicating what they are supposed to under the prevalent system operating conditions.

For each of the many NI and NoI, if the values indicated by the sensors and the inferred values concur (for the NoI), then it indicates that the system has not changed significantly from its last known condition. Hence, the assurance that the sensors are operating normally and the condition probability table parameters for each node in the network continue to maintain the same values as before (i.e., the presumed relations between the different physical variables, referred to as “processes of interest” or PoI henceforth, remains the same) increases. Conversely if these values do not match, the assurance decreases. By assigning a numerical measure to this level of assurance in the different sensors and different links in the network, and incrementing or decrementing the measure suitably each time the measured and estimated values are compared for different nodes of interest, it is possible to estimate the source of undesirable deviations in the sensor readings when they occur.

Referring to FIG. 10, in conjunction with FIGS. 1 and 8, in step 1001, an instantiation table is generated. In order to first generate an instantiation table, the types of instantiations that can be done need to be considered by considering the different nodes in the network as NI and determining the NoI and PoI associated with each such instantiation. Further, the level of assurance in the different NoI and PoI represented in the network needs to be quantified using an appropriate measure, and modifying it based on the results of comparing the measured and the inferred values for a particular NoI. The intention is to provide an intuitive metric to enable the operator to make a judgment regarding the status of different sensors and processes (i.e., whether they are potentially faulty or not) at the end of a fault detection and isolation procedure.

In one embodiment, the NI may be chosen from the set of ancestral nodes for a given NoI. This provides an intuitive starting point to implement method 1000. There are additional possibilities which include setting descendent nodes as NI and considering ancestral nodes as the NoI, or setting only the nodes in the Markov blanket of a NoI as the NI nodes, etc.

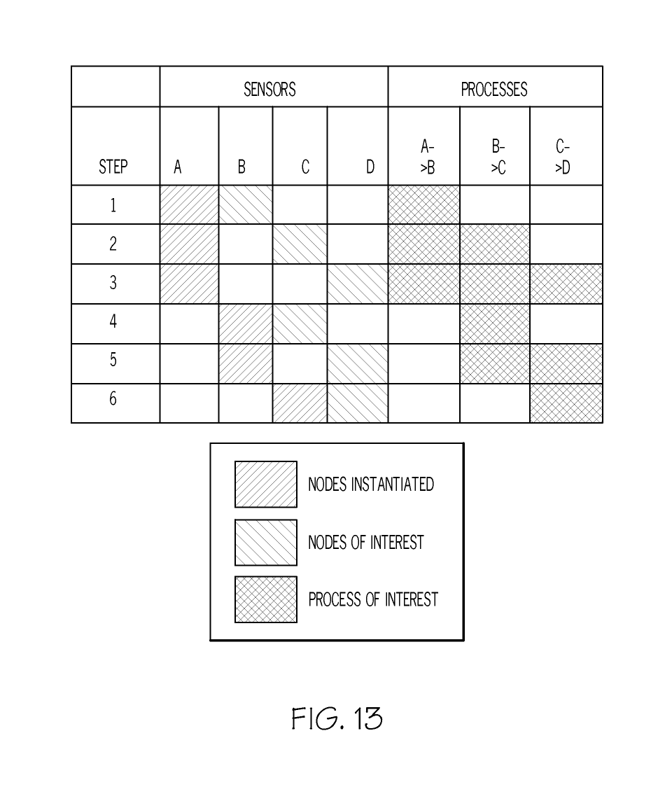

Referring to the illustrative four node Bayesian network of FIG. 12, configured in accordance with an embodiment of the present invention, the system represented by this network has four sensors corresponding to the physical variables represented by A, B, C, D and three processes A->B, B->C, and C->D. There are six possible instantiations that can be done ancestrally with this network. Note that, when the NI and the NoI are separated by a number of intermediate nodes, all the intermediate links are included as the processes of interest in that instantiation step. A comprehensive list of all such possible instantiations (considering different nodes/sensors in the network either as NI or NoI, and all the intermediate processes as PoI) can be represented as a table, referred to as the “instantiation table” for that network, which is illustrated in FIG. 13. FIG. 13 is an instantiation table for the network shown in FIG. 12 in accordance with an embodiment of the present invention. It is noted that the instantiation table may be reduced in many manners to save memory, etc. and that the principles of the present invention cover all such manners.

The process of probabilistic propagation considering each row of the instantiation table until all the rows have been exhausted is called a “fault detection and isolation cycle.”

Suppose the readings indicated by the sensors for the nodes A, B, C, D are A=a, B=b, C=c, and D=d respectively. Let a_{inf}, b_{inf}, c_{inf}, d_{inf} be the corresponding values (node states) that are obtained via probabilistic inference using the network. Using A=a as evidence, an inference is drawn regarding the most probable value of B. If it is observed that b_{inf}=b, then the assurance that the sensor for A is operating correctly, the sensor for B is operating correctly and the process A->B still maintains the presumed relation between A and B are all increased since the desired value for B was obtained as per the available conditional distribution in its condition probability table. If, on the other hand, if the values do not match, it could be indicative of a potential fault in any of the three network components (i.e., the sensors for A, B or the process A->B). A similar logic may be used to interpret the remaining rows of the instantiation table. Row 1 provides a judgment regarding the status of the sensors for A, B and the process A->B; row 2 provides a judgment regarding the status of the sensors for A, C and the processes A->B and B->C and so on.

One way to quantify the level of assurance in the different NoI and PoI is to assign unique weights to each node (sensor) and process in the network, to indicate the belief or trust or confidence that the operator has regarding their status as being faulty or not. Let these belief values be W_{S} and W_{P} respectively; where S represents a sensor corresponding to a node and P represents a process in the network. When a system and its sensors are newly deployed, the assurance that all the sensors and processes are operating correctly is quite high. But the same cannot be said for a system which has been operational for some time and its sensors have been exposed to the ambient and operating conditions. In one embodiment, in order to provide an intuitive meaning to W_{S} and W_{P}, their values are defined to lie in the interval [0, 1]. The values tending to zero imply that the assurance in that component (node/process) of the network being “healthy” is very low. Conversely, the values tending towards 1 imply perfect health.

Precise sensor reliability information is often scarce as it is highly dependent on the conditions under which the sensor is used. Although most manufacturers do provide some guidelines on sensor life under specified conditions, it is prudent to judge the health of a sensor based on analyzing its output under the prevailing conditions. With respect to judging how good a process is, the situation is more complicated since the only sources of information about the process are the sensors that measure the constituent variables in the process. Hence, at the start of each new fault detection and isolation cycle, it is assumed that there is no knowledge of the status of sensors or processes. In one embodiment, to account for this ignorance regarding the initial conditions, the beliefs for all the nodes and processes are initialized to a value of 0.5. This implies the assumption of an equal likelihood of the particular component being faulty or perfectly operational.

Referring to FIG. 10, in step 1002, the belief values W_{S} and W_{P} for all sensor and processes, respectively, are initialized to some value (e.g., 0.5).

In step 1003, a variable, i, used as a counter, is initialized to 1. This variable will be used to determine when all the rows in the instantiation table have been exhausted (referred to as “fault detection and isolation cycle” above).

In step 1004, a determination is made as to whether i is less than or equal to the number of rows in the instantiation table. If i is less than or equal to the number of rows in the instantiation table, then, in step 1005, the final belief values W_{S} and W_{P} for the sensors and processes, respectively, are outputted.

If i is not less than or equal to the number of rows in the instantiation table, then, in step 1006, the Nodes Instantiated (NI) is set as evidence to the network and propagate the values. As discussed above in connection with Table 1, the readings indicated by the sensors for one or more nodes are used as “evidence” to draw an inference regarding the most probable value for another sensor. For example, referring to the first row of the instantiation table shown in Table 1 in connection with FIG. 12, the reading by the sensor for node A as well as the process A->B are used as evidence to draw an inference for the most probable value of B.

In step 1007, a determination is made as to whether the propagated value of the Node of Interest (NOI) is the same as the measured value. In the above example, a comparison is made between the inferred value of B and the measured value of B.

If the propagated value of the Node of Interest (NOI) is not the same as the measured value, then, the belief values W_{S} and W_{P} for the associated sensors and processes are decreased in step 1008.

If, however, the propagated value of the Node of Interest (NOI) is the same as the measured value, then, in step 1009, the belief values W_{S} and W_{P} for the associated sensors and processes are increased.

Upon executing step 1008 or step 1009, the counter i is incremented by 1 in step 1010. Upon incrementing the counter i by 1, a determination is made as to whether i is less than or equal to the number of rows in the instantiation table in step 1004.

In some implementations, method 1000 may include other and/or additional steps that, for clarity, are not depicted. Further, in some implementations, method 1000 may be executed in a different order presented and that the order presented in the discussion of FIG. 10 is illustrative. Additionally, in some implementations, certain steps in method 1000 may be executed in a substantially simultaneous manner or may be omitted.

As discussed above, the belief values W_{S} and W_{P} for the associated sensors and processes are increased or decreased based on whether the propagated value of the Node of Interest (NOI) is the same or not the same as the measured value. The amount ε_{S} and ε_{P} by which W_{S} and W_{P} are modified respectively, after each step in the fault detection and isolation cycle is discussed below.

If the resultant value of the NoI (obtained by setting NI as evidence) is the same as the actual value indicated by its corresponding sensor, then beliefs for the NI and NoI under consideration and all the intermediate PoI between the NI and NoI are increased by their associated ε_{S} and ε_{P} values. In the converse situation, all these belief values are decreased by the same amount. The magnitude of ε_{S} for a particular sensor is determined by the number of times (n_{S}) it figures either as an NI or NoI in the instantiation table and is considered a fraction of the initial weight for that sensor. Similarly the magnitude of ε_{P} for a particular process is determined by the number of times (n_{P}) it occurs in the instantiation table and is also a fraction of the initial weight for that process. Thus,

$${ɛ}_{S} = \frac{{W}_{{S}_{initial}}}{{n}_{S}} and {ɛ}_{P} = \frac{{W}_{{P}_{initial}}}{{n}_{P}} \qquad ( EQ 1 )$$

The above equation is valid for W_{S}_{ᵢₙᵢₜᵢₐₗ}=W_{P}_{ᵢₙₜᵢₜᵢₐₗ}=0.5. If other initial belief values are used (for instance, when accurate sensor or process reliability data is available), the equation needs to be modified accordingly so that the condition 0≦W_{S}, W_{P}≦1 is satisfied at the end of the fault detection and isolation cycle, with a value of 0 indicating a potential fault and 1 indicating a healthy component. The final magnitudes of W_{S} and W_{P} for each sensor and each process at the end of a cycle will be considered representative of whether a particular sensor or a process is faulty or not. At the end of a single iteration of this algorithm, the sensor corresponding to the variable with W_{Smin} or the process with W_{Pmin} can be identified as being the potentially faulty. Depending on the application, a suitable threshold may also be defined to indicate the lowest acceptable values for W_{S} and W_{P}, below which sensors or processes may be deemed faulty. For instance, when there are multiple sensor faults, comparing the sorted values of W_{S} against such a threshold should provide an indication of which sensors are most likely to be faulty. This belief is further strengthened if the same results are obtained after multiple iterations of method 1000.

A case study using method 1000 in connection with the Bayesian network shown in FIG. 12 is discussed below.

Consider again the network in FIG. 12 with the corresponding instantiation table shown in Table 1. As before, let the readings indicated by the sensors for the nodes A, B, C, D be A=a, B=b, C=c, and D=d respectively under normal conditions (A=a, B=b . . . implies that the value a corresponds to one of the states of A, and so on) and let a_{inf}, b_{inf}, c_{inf}, d_{inf} be the corresponding values obtained via probabilistic inference using the network. The W_{S} and W_{P} values for each of the sensors and processes considered in the instantiation table are calculated based on the ε values given by the following:

$$\begin{matrix}{ɛ}_{A} = \frac{0.5}{3} = 0.1667 & {ɛ}_{B} = \frac{0.5}{3} = 0.1667 & {ɛ}_{C} = \frac{0.5}{3} = 0.1667 & {ɛ}_{D} = \frac{0.5}{3} = 0.1667 \\ {ɛ}_{A -> B} = \frac{0.5}{3} = 0.1667 & {ɛ}_{B -> C} = \frac{0.5}{4} = 0.125 & {ɛ}_{C -> D} = \frac{0.5}{3} = 0.1667 & \end{matrix}$$

Suppose the readings indicated by the sensors are A=a, B=b′≠b (where b′ indicates that, due to a sensor fault, the state of B corresponding to the value b′ is different from the state of B corresponding to the value b), C=c, and D=d respectively.

Method 1000 may start with an assumption of ignorance regarding the status of any sensor or process. This implies that there is an equal chance that any of the sensors or processes could be at fault. Therefore the initial beliefs in the different sensors and processes are given by the following:

| | | | |
|---|---|---|---|
| W_{A} = 0.5 | W_{B} = 0.5 | W_{C} = 0.5 | W_{D} = 0.5 |
| W_{A->B} = 0.5 | W_{B->C} = 0.5 | W_{C->D} = 0.5 | |

Since the condition probability table parameters in the network are still unchanged after the last update when all the sensors and processes were deemed to be working correctly, after the first instantiation, the value b_{inf} will not be the same as b′. Hence, the beliefs in the sensors for A and B and the process A->B will be decreased by their corresponding ε values. The revised belief values now become:

| W_{A} = 0.5-0.1667 = | W_{B} = 0.5-0.1667 = | W_{C} = 0.5 | W_{D} = 0.5 |
|---|---|---|---|
| 0.3333 | 0.3333 | | |
| W_{A->B} = 0.5-0.1667 = | W_{B->C} = 0.5 | W_{C->D} = 0.5 | |
| 0.3333 | | | |

After the second instantiation, since the sensor for C is not faulty and the processes A->B and B->C are also not faulty (as determined by the previous fault detection and isolation cycle), the value obtained after probabilistic propagation i.e., c_{inf} is expected to be the same as the reading c from the sensor for node C. Thus, the beliefs in the sensors A and C and the beliefs in the intermediate the processes A->B and B->C are increased by their respective ε values. The revised beliefs after the second instantiation in the cycle are the following:

$$\begin{matrix}\begin{matrix}{W}_{A} = 0.3333 + 0.1667 \\ = 0.5 \end{matrix} & {W}_{B} = 0.3333 & \begin{matrix}{W}_{C} = 0.5 + 0.1667 \\ = 0.6667 \end{matrix} & {W}_{D} = 0.5 \\ \begin{matrix}{W}_{A -> B} = 0.3333 + 0.1667 \\ = 0.5 \end{matrix} & \begin{matrix}{W}_{B -> C} = 0.5 + 0.125 \\ = 0.625 \end{matrix} & {W}_{C -> D} = 0.5 & \end{matrix}$$

Repeating the above procedure for each step in the instantiation table, the results obtained are shown in Table 2. Thus, after the complete cycle, the belief in the sensor for node B is zero, whereas, the belief in the other sensors and processes are higher, as they should be.

TABLE 2
Change in W_{S} and W_{P} Values with a Faulty Sensor

| | Sensors | | | | Processes | | |
|---|---|---|---|---|---|---|---|
| Step | A | B | C | D | A−>B | B−>C | C−>B |
| 0 | 0.5 | 0.5 | 0.5 | 0.5 | 0.5 | 0.5 | 0.5 |
| 1 | 0.3333 | 0.3333 | 0.5 | 0.5 | 0.3333 | 0.5 | 0.5 |
| 2 | 0.5 | 0.3333 | 0.6667 | 0.5 | 0.5 | 0.625 | 0.5 |
| 3 | 0.6667 | 0.3333 | 0.6667 | 0.6667 | 0.6667 | 0.750 | 0.6667 |
| 4 | 0.6667 | 0.1667 | 0.5 | 0.6667 | 0.6667 | 0.625 | 0.6667 |
| 5 | 0.6667 | 0.0000 | 0.5 | 0.5 | 0.6667 | 0.5 | 0.5 |
| 6 | 0.6667 | 0.0000 | 0.6667 | 0.6667 | 0.6667 | 0.5 | 0.6667 |

These beliefs are calculated after a single sample of data. If the same result is obtained in consecutive isolation cycles, then it is indicative of a confirmed fault in the sensor for node B. The number of cycles required is based on the application requirement and operator judgment. Once a sensor fault has been determined with certainty, the operator can also choose to modify the isolation table by eliminating the steps involving the sensor for node B either as an instantiated node or as a node of interest (steps 1, 4, and 5 in the instantiation table). Although this does not provide any additional information, with the remaining instantiations, since all the other sensors and processes are operating correctly, the corresponding belief values will ideally attain a value of 1 in the subsequent isolation cycles. However, at this point, these values may be used by the system operator to decide whether or not to continue using the data from the sensor for node B.

An example of a process fault is now discussed below. Since the Bayesian network represents the causal relations among all the variables of interest in the system, in case of a process fault, the effect of the fault is noticed in all the variables downstream of the process and not confined just to the variables in the process itself. This is manifested as a variation in the readings of all the associated sensors. In other words, a fault in the process B->C will be reflected as deviations in the readings of the sensors for nodes C and D from their ideal values (as obtained from the network). Thus, in this case, after the first instantiation in the instantiation table, since the process A->B is not faulty and the sensors for A and B are also not faulty, the value b_{inf} will agree with the reading b from the sensor for node B. Thus, the beliefs in the sensors and processes are revised as follows:

$$\begin{matrix}\begin{matrix}{W}_{A} = 0.5 + 0.1667 \\ = 0.6667 \end{matrix} & \begin{matrix}{W}_{B} = 0.5 + 0.1667 \\ = 0.6667 \end{matrix} & {W}_{C} = 0.5 & {W}_{D} = 0.5 \\ \begin{matrix}{W}_{A -> B} = 0.5 + 0.1667 \\ = 0.6667 \end{matrix} & {W}_{B -> C} = 0.5 & {W}_{C -> D} = 0.5 & \end{matrix}$$

In the next four instantiations, when A or B is the instantiated node, since the faulty process B->C is involved as a process of interest, the values c and d indicated by the sensors will be different from the inferred values c_{inf} and d_{inf}. In the last step of the isolation cycle, only sensors for C and D and the process C->D are involved. Since none of these components are faulty, the measured and the inferred values d and d_{inf} are found to be in agreement. The variation in all the beliefs in this scenario is shown in Table 3.

TABLE 3
Change in W_{S} and W_{P} Values with a Faulty Process

| | Sensors | | | | Processes | | |
|---|---|---|---|---|---|---|---|
| Step | A | B | C | D | A−>B | B−>C | C−>D |
| 0 | 0.5 | 0.5 | 0.5 | 0.5 | 0.5 | 0.5 | 0.5 |
| 1 | 0.6667 | 0.6667 | 0.5 | 0.5 | 0.6667 | 0.5 | 0.5 |
| 2 | 0.5 | 0.6667 | 0.3333 | 0.5 | 0.5 | 0.375 | 0.5 |
| 3 | 0.3333 | 0.6667 | 0.3333 | 0.3333 | 0.3333 | 0.25 | 0.3333 |
| 4 | 0.3333 | 0.5 | 0.1667 | 0.3333 | 0.3333 | 0.125 | 0.3333 |
| 5 | 0.3333 | 0.3333 | 0.1667 | 0.1667 | 0.3333 | 0.0000 | 0.1667 |
| 6 | 0.3333 | 0.3333 | 0.3333 | 0.3333 | 0.3333 | 0.0000 | 0.3333 |

It is observed that the belief in the process B->C is reduced to zero, whereas, the beliefs in all the other sensors and processes are higher. These belief values can be used to alert the operator that a potential fault may exist in the system. As in the earlier case, the process B->C can be declared as being faulty with certainty if the same results are obtained after multiple samples have been analyzed (i.e., after a certain number of fault detection and isolation cycles). Thus, the algorithm is able to correctly distinguish between a sensor and a process fault (i.e., it does not interpret the deviations in the sensors corresponding to the nodes C and D as multiple sensor faults). The final belief values are indicative of the trustworthiness of a specific sensor or process. This knowledge can be immensely useful when updating the model parameters (i.e., condition probability table values of the various nodes) and eventually the stored performance maps (embedded process parameters are devised from conditional probability tables that are used to illustrate the performance of the system at a point in time).

Referring to step 804 of FIG. 8, as discussed above, the condition probability table is updated if the anomalous behavior is caused by a process fault. When the Bayesian network for a system is initially constructed, the model parameters (conditional probability tables) for the nodes are decided based either on an expert's opinion regarding how the system is likely to behave under different scenarios or on extensive empirical data. To represent the status of the system at any instant as accurately as possible there is a need to refresh or update the conditional probability tables with fresh data on a periodic basis. This is referred to as ‘learning’ the model parameters.

In one embodiment, the values of W_{S} and W_{P} are used as the decision criterion to modify a learning rate η and also to determine the magnitude of this change. The learning rate η determines the amount by which the past data is weighted to update the parameters. As η→0, the value of past data is more heavily weighted and the model parameters remain practically unchanged. Conversely, as η→1, the newly available or present data is assigned a higher importance in determining the updated value of the parameters. When all the sensors and processes are found to be operating correctly (as indicated by W_{S} and W_{P} values which are ˜1 or above user-defined thresholds), the learning rates need to be adjusted to update the parameters based on the data sample analyzed. Let η_{PA}_{ⱼ}_{X}_{ᵢ}^{L} and η_{PA}_{ⱼ}_{X}_{ᵢ}^{H} be the lowest and the highest learning rates, respectively, for a particular combination of node value Xᵢ and its parents in the configuration PAⱼ. If NS is the number of data samples that have been previously analyzed to determine the learning rate, the new value of η_{PAj,Xi} for the next learning cycle can be calculated as follows (Equation EQ 2):

$${η}_{{PA}_{j} {X}_{i}} = {η}_{{PA}_{j} {X}_{i}}^{L} + \frac{{η}_{{PA}_{j} {X}_{i}}^{H} - {η}_{{PA}_{j} {X}_{i}}^{L}}{1 + NS}$$

As the number of data samples increases, the learning rate decreases from η_{PA}_{ⱼ}_{X}_{ᵢ}^{H}, theoretically attaining a value of η_{PA}_{ⱼ}_{X}_{ᵢ}^{L} (or zero if η_{PA}_{ⱼ}_{X}_{ᵢ}^{L}=0) after an infinite number of samples have been analyzed. Practically, the learning rate keeps decreasing but remains a finite value. If, however, the sensor corresponding to a node Xᵢ is identified as being potentially faulty at the end of the iteration of method 1000 preceding the latest data sample (its W_{S} value is ˜0 or lesser than a user-defined threshold), then the η_{PAj,Xi} for all the columns in the condition probability table of that node is set to a value of zero immediately. Since this sensor determines the parent configurations PAᵣ for all the child nodes of Xᵢ, such as, for example, Yₖ, the learning rates for all those nodes, η_{PAr,Yk} are also set to zero immediately.

This is done to prevent the corruption of the existing condition probability table parameter values of Xᵢ, in the situation where the corresponding sensor is actually faulty. If, however, after subsequent fault isolation cycles, it turns out that the sensor is not faulty (or if a faulty sensor has been repaired/replaced), the learning rate may be reset to a value used just preceding the cycle of method 1000 in which an alarm for the faulty sensor was first raised.

Now consider a situation where at the end of the cycle of method 1000 it is determined that all the sensors are operating correctly (all W_{S} values are ˜1 or above user-defined thresholds) but there is a process fault (one or more W_{P} values are ˜0 or below user-defined thresholds). In this case, if η values are too low, the model parameters cannot be updated quickly enough to represent the variation in the system dynamics. To decide the magnitude of increase in the 11 values, the W_{S} and W_{P} values can again be used. Suppose PAⱼ≡{P₁^{a}, P₂^{b}, . . . Pₘ^{q}} represent a specific configuration of the parents P₁, P₂, . . . , Pₘ of a node Xᵢ and there is a fault in the k^{th} process Pₖ->Xᵢ. The new increased 11 for the combination of PAⱼ and Xᵢ, may be calculated as follows (Equation EQ 3):

η_{PA}_{ⱼ}_{X}_{ᵢ}^{new}=η_{PA}_{ⱼ}_{X}_{ᵢ}^{current}+(1−W_{P}_{_{avg}})(η_{PA}_{ⱼ}_{X}_{ᵢ}^{H}−η_{PA}_{ⱼ}_{X}_{ᵢ}^{current})

where W_{P}_{_{avg}} is the average of the W_{P} values obtained by considering all the processes that terminate at X_{i.}, i.e., P₁->Xᵢ, P₂->Xᵢ, . . . Pₘ->Xᵢ. The new value of η is now determined by the condition of the system. Since all the sensors are deemed to be operating correctly, the faultier the system is (low W_{P} values for one or more processes), the higher is the learning rate. This helps update the parameters quickly and can help improve the output from the higher level condition-based maintenance algorithms. If all the processes that terminate at Xᵢ are operating correctly, and all the sensors are also operating normally the learning rate remains unchanged. In the extreme scenario when all the processes are faulty (W_{P}_{_{avg}}≈0), then η is set to its highest value. For any other intermediate condition (0<W_{P}_{_{avg}}≦1), η is increased from its present value.

Referring to FIG. 8, if no anomalous behavior was identified or if the anomalous behavior was caused by a sensor fault or upon updating the conditional probability table, then, in step 805, different operational regimes are utilized to determine the set of sensors that can be enabled or disabled in real time.

In most applications, following some preliminary processing at the sensor-level, the signals from all the sensors monitoring the system are sent to a central location for further processing or for use in deriving higher level information. This configuration is commonly observed in PC-based data acquisition and control of systems like Electro-Mechanical Actuators (EMA), mobile robots, etc. With a limited number of sensors, a point-to-point connection technique is sufficient to connect the sensors directly to the PC without significant design or hardware overhead. However, such an arrangement requires complex cabling arrangements. Hence a bus topology is often utilized wherein all the sensors use a common set of resources for data transmission. In a digital fieldbus system, multiple sensors are connected via shared digital communication lines (thereby reducing the number of cables) to transmit/receive data more efficiently on an as-needed basis. When such an arrangement is utilized, the cumulative data bandwidth and latency required for all the sensors being considered plays a significant role in the selection of the appropriate bus. This is largely dictated by factors like the type of the sensor output, quantity of output data generated in a specific time period, sampling rate used for the different sensors, mode of acquisition from multiple sensors (simultaneous/multiplexed), etc.

Consider for example, a motor equipped with an incremental encoder producing 10,000 counts per revolution (cpr) and rotating at a moderate speed, such as, for example, 600 rpm. This yields an output signal frequency of 0.1 MHz. As the motor speed increases, the volume of output data from the encoder also increases. In addition, the motor may be instrumented with other sensors like current, voltage, temperature, etc. which may generate additional volumes of data. To acquire all this information accurately, it needs to be sampled at a high rate. Hence, in addition to the transmission bandwidth, the data acquisition hardware also needs to be capable of handling the frequency requirements for sampling.

With fewer sensors, the total bandwidth requirements are moderate and it may be possible to sample all the sensors simultaneously with the available data bus and acquisition hardware resources. However, if the system has a large number of sensors which also need to be sampled at high rates, the number of high-speed data acquisition channels required increases (to accommodate the increased bandwidth/sampling requirements) which typically leads to higher overall costs. Often, as a compromise between cost and performance requirements, a limited number of data acquisition channels are used (capable of handling large amounts of data at high frequencies) and the available resources are distributed across all the sensor channels, by using a lower sampling rate, polling the sensors periodically instead of continuous acquisition, etc.

The use of a Bayesian network to model the system allows the flexibility of inferring the value of any node/variable in the network (query) using the value of any other node/variable (evidence) in an inferencing process. This capability can be exploited for managing the available resources (bandwidth/sampling rate capability) in certain operating regimes of the system, where it may not be possible to accurately acquire data from sensors with demanding requirements (i.e., those that require a high bandwidth/sampling rate). For instance, in the example cited earlier, if the motor rotates at 6000 rpm, the output frequency from the encoder rises to 1 MHz. If the associated data bus and acquisition hardware are capable of accommodating only 0.5 MHz, it might be more prudent to allocate the available resources to sensors with modest resource requirements, such as, for example, the voltage sensors which need to be sampled at only 1 kHz to acquire their output data with the best possible resolution/sampling rates. This data may then be used to infer the values of other variables that have higher bandwidth/sampling rate needs such as motor speed (within reasonable accuracy) using a Bayesian network that includes the motor voltage and speed as nodes.

In step 806, the connection and link strength are utilized to determine the sensor that it most likely to give a best estimate of another measured.

The structure of the Bayesian network explicitly represents the conditional dependencies/independencies between the different variables of interest in the system (nodes). The strength of these conditional relationships is encoded in the conditional probability parameters of the conditional probability tables for all the non-root nodes in the network. However, in any system, a particular set of physical variables, say X, may have a greater influence on a set of variables Z than another set of variables Y. In such cases, in the scenario that information from one or more sensors corresponding to the variables in Z becomes unavailable, it would be desirable to use the information available from the sensors corresponding to the variables in X rather than in the set Y, in order to infer the values of the variables of interest in the set Z.

An approach using which the extent of such influence may be quantified is by using the concept of link and connection strengths. The connection strength measures the strength between any two nodes in the network (without accounting for the path between the two), whereas, link strength specifically calculates the strength along a particular link between two adjacent nodes.

The connection and link strength are based on information theory concepts of entropy and mutual information. The entropy and conditional entropy of a discrete random variable are given as follows (Equations EQ 4, EQ 5, respectively):

$$U ( A ) = - {\sum }_{{a}_{i}} P ( {a}_{i} ) {log}_{2} P ( {a}_{i} )$$

$$U ( B \vert A ) = - {\sum }_{{a}_{i}} P ( {a}_{i} ) U ( B \vert {a}_{i} )$$

The connection strength between any two nodes/variables A and B in the network, is defined by how strongly the knowledge of the state of A affects the state of B and vice versa and quantifies it using the concept of mutual information as follows (Equation EQ 6):

$$CS ( A , B ) = I ( A , B ) = U ( A ) - U ( B \vert A ) = {\sum }_{a , b} P ( a , b ) {log}_{2} ( \frac{P ( a , b )}{P ( a ) P ( b )} )$$

The link strength is defined specifically for the relation A->B (i.e., A is the parent and B is its child). If C represents the set of other parents of B where C={C₁, C₂ . . . Cₙ} and c represents the set of states of all the nodes Cᵢ, then the link strength is defined as follows (Equation EQ 7):

$$LS ( A \to B ) = {\sum }_{c} {P}_{pr} ( c ) {\sum }_{a} {P}_{pr} ( a ) {\sum }_{b} P ( b \vert a , c ) {log}_{2} \frac{P ( b \vert a , c )}{{P}_{pr} ( b \vert c )}$$

where Pₚᵣ is an approximation of the prior probability of the node being in a particular state and is approximated by averaging the conditional probabilities of that node over all its parent state combinations. For any application, the values of link strengths and connection strengths may be calculated between different sets of variables and used to determine the most appropriate sensors to use (i.e., if the corresponding nodes have high link/connection strengths indicating that the associated variables are strongly correlated) to infer the information corresponding to faulty or degrading sensors.

In step 807, the particular type of query is received based on computational constraints. The Bayesian network compactly represents the joint probability distribution of all the variables represented by the nodes in the network. That is, the network structure and the condition probability tables for the different nodes, represent a comprehensive database that can be queried in different ways to obtain different types of information regarding the system and its sensors. Depending on the application and the operating regime of the system, choosing the right type of query (e.g., probability of evidence, prior and posterior marginal distributions, Maximum Aposteriori Hypothesis (MAP), Most Probably Explanation (MPE)) can provide information that is of greater value to the system operator for decision-making under the given computational requirements. In other words, since each type of query has different computational requirements, the system operator should pose queries based on the decision making requirements and the computational constraints.

In step 808, the value of a sensor node is inferred using an appropriate inferencing algorithm based on time, accuracy and computational constraints. There are many different types of algorithms (e.g., approximate algorithms, exact algorithms) used to infer the value of a sensor node. Such an algorithm should be selected by the system operator based on time, accuracy and computational constraints.

In some implementations, method 800 may include other and/or additional steps that, for clarity, are not depicted. Further, in some implementations, method 800 may be executed in a different order presented and that the order presented in the discussion of FIG. 8 is illustrative. Additionally, in some implementations, certain steps in method 800 may be executed in a substantially simultaneous manner or may be omitted.

Although the method, system and computer program product are described in connection with several embodiments, it is not intended to be limited to the specific forms set forth herein, but on the contrary, it is intended to cover such alternatives, modifications and equivalents, as can be reasonably included within the spirit and scope of the invention as defined by the appended claims.

1. A method for distinguishing between a sensor fault and a process fault in a physical system, the method comprising:
designing a Bayesian network to probabilistically relate sensor data in said physical system, wherein said physical system comprises a plurality of sensors;
collecting said sensor data from said plurality of sensors in said physical system;
deriving a conditional probability table based on said collected sensor data and said design of said Bayesian network;
identifying anomalous behavior in said physical system; and
determining, by a processor, one of said sensor fault and said process fault caused said identified anomalous behavior using belief values for said plurality of sensors and a plurality of processes in said physical system, wherein said belief values indicate a level of trust regarding the status of its associated sensors and processes not being faulty.

2. The method as recited in claim 1 further comprising:
inferring a value to be generated by one of said plurality of sensors of said physical system using one or more values sampled from one or more other sensors of said plurality of sensors and using one or more processes of said plurality of processes.

3. The method as recited in claim 2 further comprising:
increasing said belief values for said one or more other sensors and said one or more processes used in inferring said value to be generated by said one of said plurality of sensors in response to said value to be generated by said one of said plurality of sensors matching a value sampled for said one of said plurality of sensors.

4. The method as recited in claim 2 further comprising:
decreasing said belief values for said one or more other sensors and said one or more processes used in inferring said value to be generated by said one of said plurality of sensors in response to said value to be generated by said one of said plurality of sensors not matching a value sampled for said one of said plurality of sensors.

5. The method as recited in claim 1 further comprising:
iteratively inferring a value to be generated by a different sensor of said plurality of sensors using one or more values sampled from one or more other sensors of said plurality of sensors and using one or more processes of said plurality of processes.

6. The method as recited in claim 5 further comprising:
increasing at an end of an iteration said belief values for said one or more other sensors and said one or more processes used in inferring said value to be generated by one of said plurality of sensors in response to said value to be generated by said one of said plurality of sensors matching a value sampled for said one of said plurality of sensors.

7. The method as recited in claim 5 further comprising:
decreasing at an end of an iteration said belief values for said one or more other sensors and said one or more processes used in inferring said value to be generated by one of said plurality of sensors in response to said value to be generated by said one of said plurality of sensors not matching a value sampled for said one of said plurality of sensors.

8. The method as recited in claim 1 further comprising:
identifying a sensor of said plurality of sensors that is important for operational reasons; and
maximizing a number of links directly inbound/outbound onto a node for said identified sensor in said Bayesian network.

9. The method as recited in claim 1 further comprising:
identifying a first sensor of said plurality of sensors that is most likely to provide a best estimate of a second sensor of said plurality of sensors based on node distance between a node of said first sensor and a node of said second sensor in said Bayesian network.

10. The method as recited in claim 1 further comprising:
identifying a first sensor of said plurality of sensors that is most likely to provide a best estimate of a second sensor of said plurality of sensors based on connection and link strength between a node of said first sensor and a node of said second sensor in said Bayesian network.

11. The method as recited in claim 1, wherein said physical system comprises one of the following: a nuclear reactor, an airplane, a wind turbine, a power distribution system, an automobile, a drilling rig, a chemical plant and a patient health monitoring system.

12. The method as recited in claim 1 further comprising:
updating said conditional probability table in response to determining said process fault caused said identified anomalous behavior.

13. The method as recited in claim 1 further comprising:
introducing additional nodes, representing redundant sensors, into said Bayesian network.

14. The method as recited in claim 1 further comprising:
displaying an indication that one of said sensor fault and said process fault caused said identified anomalous behavior.

15. A computer program product embodied in a computer readable storage medium for distinguishing between a sensor fault and a process fault in a physical system, the computer program product comprising the programming instructions for:
designing a Bayesian network to probabilistically relate sensor data in said physical system, wherein said physical system comprises a plurality of sensors;
collecting said sensor data from said plurality of sensors in said physical system;
deriving a conditional probability table based on said collected sensor data and said design of said Bayesian network;
identifying anomalous behavior in said physical system; and
determining one of said sensor fault and said process fault caused said identified anomalous behavior using belief values for said plurality of sensors and a plurality of processes in said physical system, wherein said belief values indicate a level of trust regarding the status of its associated sensors and processes not being faulty.

16. The computer program product as recited in claim 15 further comprising the programming instructions for:
inferring a value to be generated by one of said plurality of sensors of said physical system using one or more values sampled from one or more other sensors of said plurality of sensors and using one or more processes of said plurality of processes.

17. The computer program product as recited in claim 16 further comprising the programming instructions for:
increasing said belief values for said one or more other sensors and said one or more processes used in inferring said value to be generated by said one of said plurality of sensors in response to said value to be generated by said one of said plurality of sensors matching a value sampled for said one of said plurality of sensors.

18. The computer program product as recited in claim 16 further comprising the programming instructions for:
decreasing said belief values for said one or more other sensors and said one or more processes used in inferring said value to be generated by said one of said plurality of sensors in response to said value to be generated by said one of said plurality of sensors not matching a value sampled for said one of said plurality of sensors.

19. The computer program product as recited in claim 15 further comprising the programming instructions for:
iteratively inferring a value to be generated by a different sensor of said plurality of sensors using one or more values sampled from one or more other sensors of said plurality of sensors and using one or more processes of said plurality of processes.

20. The computer program product as recited in claim 19 further comprising the programming instructions for:
increasing at an end of an iteration said belief values for said one or more other sensors and said one or more processes used in inferring said value to be generated by one of said plurality of sensors in response to said value to be generated by said one of said plurality of sensors matching a value sampled for said one of said plurality of sensors.

21. The computer program product as recited in claim 19 further comprising the programming instructions for:
decreasing at an end of an iteration said belief values for said one or more other sensors and said one or more processes used in inferring said value to be generated by one of said plurality of sensors in response to said value to be generated by said one of said plurality of sensors not matching a value sampled for said one of said plurality of sensors.

22. The computer program product as recited in claim 15, wherein said physical system comprises one of the following: a nuclear reactor, an airplane, a wind turbine, a power distribution system, an automobile, a drilling rig, a chemical plant and a patient health monitoring system.

23. The computer program product as recited in claim 15 further comprising the programming instructions for:
updating said conditional probability table in response to determining said process fault caused said identified anomalous behavior.

24. The computer program product as recited in claim 15 further comprising the programming instructions for:
displaying an indication that one of said sensor fault and said process fault caused said identified anomalous behavior.

25. A system, comprising:
a memory unit for storing a computer program for distinguishing between a sensor fault and a process fault in a physical system; and
a processor coupled to said memory unit, wherein said processor, responsive to said computer program, comprises:
circuitry for designing a Bayesian network to probabilistically relate sensor data in said physical system, wherein said physical system comprises a plurality of sensors;
circuitry for collecting said sensor data from said plurality of sensors in said physical system;
circuitry for deriving a conditional probability table based on said collected sensor data and said design of said Bayesian network;
circuitry for identifying anomalous behavior in said physical system; and
circuitry for determining one of said sensor fault and said process fault caused said identified anomalous behavior using belief values for said plurality of sensors and a plurality of processes in said physical system, wherein said belief values indicate a level of trust regarding the status of its associated sensors and processes not being faulty.

26. The system as recited in claim 25, wherein said processor further comprises:
circuitry for inferring a value to be generated by one of said plurality of sensors of said physical system using one or more values sampled from one or more other sensors of said plurality of sensors and using one or more processes of said plurality of processes.

27. The system as recited in claim 26, wherein said processor further comprises:
circuitry for increasing said belief values for said one or more other sensors and said one or more processes used in inferring said value to be generated by said one of said plurality of sensors in response to said value to be generated by said one of said plurality of sensors matching a value sampled for said one of said plurality of sensors.

28. The system as recited in claim 26, wherein said processor further comprises:
circuitry for decreasing said belief values for said one or more other sensors and said one or more processes used in inferring said value to be generated by said one of said plurality of sensors in response to said value to be generated by said one of said plurality of sensors not matching a value sampled for said one of said plurality of sensors.

29. The system as recited in claim 25, wherein said processor further comprises:
circuitry for iteratively inferring a value to be generated by a different sensor of said plurality of sensors using one or more values sampled from one or more other sensors of said plurality of sensors and using one or more processes of said plurality of processes.

30. The system as recited in claim 29, wherein said processor further comprises:
circuitry for increasing at an end of an iteration said belief values for said one or more other sensors and said one or more processes used in inferring said value to be generated by one of said plurality of sensors in response to said value to be generated by said one of said plurality of sensors matching a value sampled for said one of said plurality of sensors.

31. The system as recited in claim 29, wherein said processor further comprises:
circuitry for decreasing at an end of an iteration said belief values for said one or more other sensors and said one or more processes used in inferring said value to be generated by one of said plurality of sensors in response to said value to be generated by said one of said plurality of sensors not matching a value sampled for said one of said plurality of sensors.

32. The system as recited in claim 25, wherein said physical system comprises one of the following: a nuclear reactor, an airplane, a wind turbine, a power distribution system, an automobile, a drilling rig, a chemical plant and a patient health monitoring system.

33. The system as recited in claim 25, wherein said processor further comprises:
circuitry for updating said conditional probability table in response to determining said process fault caused said identified anomalous behavior.

34. The system as recited in claim 25, wherein said processor further comprises:
circuitry for displaying an indication that one of said sensor fault and said process fault caused said identified anomalous behavior.
